(19) United States
(12) Patent Application Publication
(10) Pub. No.: US 2020/0388488 A1
(43) Pub. Date: Dec. 10, 2020

(54) BOTTOM-UP CURING OF DIELECTRIC FILMS IN INTEGRATED CIRCUITS

(71) Applicant: International Business Machines Corporation, Armonk, NY (US)

(72) Inventors: Devika Sil, Rensselaer, NY (US); Oleg Gluschenkov, Tannersville, NY (US); Yasir Sulehria, Latham, NY (US); Hosadurga Shobha, Niskayuna, NY (US)

(21) Appl. No.: 16/431,121

(22) Filed: Jun. 4, 2019

(51) Int. Cl. H01L 21/02; H05K 3/46; H01L 21/48

(52) U.S. Cl. CPC H01L 21/02348; H05K 3/4673; H05K 2203/092; H05K 2203/1105; H01L 21/4857

(57) ABSTRACT

Embodiments of the invention include a method of forming a multi-layer integrated circuit (IC) structure that includes forming a passive energy source formed from a conductive metal. A dielectric target layer is formed over the first energy source. An active energy source is used to generate electromagnetic radiation having a predetermined wavelength, wherein the dielectric target layer is substantially transparent to the electromagnetic radiation at the predetermined wavelength. The dielectric target layer is exposed to the electromagnetic radiation by transmitting the electromagnetic radiation into and through the dielectric target layer to impact the passive energy source. The passive energy source is configured to, based at least in part on being exposed to the electromagnetic radiation, absorb the electromagnetic radiation, experience a conductive material temperature increase such that the conductive material generates heat energy, and emit the generated heat energy to the dielectric target layer.

### BACKGROUND

The present invention generally relates to fabrication methods and resulting structures for integrated circuit (IC) wafers. More specifically, the present invention relates to fabrication methodologies and resulting structures for hardening weakened low-k dielectric films of an IC wafer using a bottom-up curing technique.

ICs are fabricated in a series of stages, including a front-end-of-line (FEOL) stage, a middle-of-line (MOL) stage and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another.

Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

The insulating material in the BEOL layers of an IC is often cured during IC fabrication in order to achieve desired mechanical properties of the insulating material. Thermal budgets for such curing processes are limited by temperature sensitive structures and often do not exceed temperatures higher than 400° C. for 10 minutes.

### SUMMARY

Embodiments of the invention are directed to a method of forming a multi-layer integrated circuit (IC) structure. A non-limiting example of the method includes forming a passive energy source formed from a conductive metal. A target layer is formed over the conductive metal, wherein the target layer is a dielectric. An active energy source is used to generate electromagnetic radiation having a predetermined wavelength, wherein the dielectric target layer material is substantially transparent to the electromagnetic radiation at the predetermined wavelength. The active energy source is used to expose the conductive metal to the electromagnetic radiation by transmitting the electromagnetic energy into and through the dielectric target layer for a predetermined duration to impact the conductive metal, wherein the conductive metal substantially absorbs the electromagnetic radiation at the predetermined wavelength. The conductive metal is configured to, based at least in part on being exposed to the electromagnetic radiation, absorb the electromagnetic radiation, experience a conductive metal temperature increase such that the conductive metal generates heat energy and emits the generated heat energy to the dielectric target layer.

Embodiments of the invention are directed to a method of forming a multi-layer IC structure. A non-limiting example of the method forming a first IC layer above a substrate, wherein the first IC layer includes a network of interconnect structures formed from conductive material, wherein the network of interconnect structures is configured to communicatively couple electronic devices of the IC to one another. A second IC layer is formed above the first IC layer, wherein the second IC layer is formed from a porous dielectric material, and wherein the second IC layer further includes a top surface and a bottom surface. An electromagnetic energy source is used to generate electromagnetic radiation having a predetermined wavelength, wherein the dielectric material of the second IC layer material is substantially transparent to the electromagnetic energy at the predetermined wavelength. The electromagnetic energy source is used to expose the network of interconnect structures to the electromagnetic radiation by transmitting the electromagnetic radiation into and through the second IC layer to impact the network of interconnect structures, wherein the conductive material of the network of conductive interconnect structures substantially absorbs the electromagnetic radiation at the predetermined wavelength. The conductive material of the network of interconnect structures is configured to, based at least in part on being exposed to the electromagnetic radiation, absorb the electromagnetic radiation, experience a conductive material temperature increase sufficient to chemically crosslink the backbone network in the second IC layer and emit heat energy to the bottom surface of the second IC layer.

Embodiments of the invention are directed to a multi-layer IC structure. A non-limiting example of the IC structure includes a first IC layer formed above a substrate, wherein the first IC layer includes a network of interconnect structures formed from a conductive material, and wherein the network of interconnect structures is configured to communicatively couple electronic devices of the IC. A second IC layer is formed above the first IC layer, wherein the second IC layer is formed from a dielectric material that includes a top region, a bottom region, and a central region positioned between the top region and the bottom region. The top region has a top region backbone network strength, the bottom region has a bottom region backbone network strength, and the central region has a central region backbone network strength, wherein the bottom region backbone network strength is higher than the central region backbone network strength.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a portion of an IC wafer in accordance with aspects of the invention;

FIG. 2 depicts a diagram illustrating a pulsed wave of electromagnetic radiation configured in accordance with aspects of the invention;

FIGS. 3-6 depict the results of fabrication operations for forming IC structures in accordance with aspect of the invention, in which:

FIG. 3 depicts a cross-sectional view of a representative section of an IC after fabrication operations according to embodiments of the invention;

FIG. 4 depicts a cross-sectional view of a representative section of an IC after fabrication operations according to embodiments of the invention;

FIG. 5 depicts a cross-sectional view of a representative section of an IC after fabrication operations according to embodiments of the invention; and

FIG. 6 depicts a cross-sectional view of a representative section of an IC after fabrication operations according to embodiments of the invention;

FIG. 7 depicts a cross-sectional view of a representative section of an IC after fabrication operations according to embodiments of the invention;

FIG. 8 depicts a cross-sectional view of a representative section of an IC after fabrication operations according to embodiments of the invention;

FIG. 9 depicts a cross-sectional view of a representative section of an IC after fabrication operations according to embodiments of the invention;

FIG. 10 depicts experimental data according to the embodiments of the invention;

FIG. 11 depicts experimental data according to the embodiments of the invention;

FIG. 12 depicts experimental data according to the embodiments of the invention; and

FIG. 13 depicts experimental data according to the embodiments of the invention;

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two- or three-digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, semiconductor devices are used in a variety of electronic and electro-optical applications. ICs are typically formed from various circuit configurations of semiconductor devices (e.g., transistors, capacitors, resistors, etc.) and conductive interconnect layers (known as metallization layers) formed on semiconductor wafers. Alternatively, semiconductor devices can be formed as monolithic devices, e.g., discrete devices. Semiconductor devices and conductive interconnect layers are formed on semiconductor wafers by depositing many types of thin films of material over the semiconductor wafers, patterning the thin films, doping selective regions of the semiconductor wafers, etc.

In contemporary semiconductor fabrication processes, a large number of semiconductor devices and conductive interconnect layers are fabricated. More specifically, during the first portion of chip-making (i.e., the FEOL stage), the individual components (transistors, capacitors, etc.) are fabricated on the wafer. The MOL stage follows the FEOL stage and typically includes process flows for forming the contacts and other structures that communicatively couple to active regions (e.g., gate, source, and drain) of the device element. For example, the silicidation of source/drain regions, as well as the deposition of metal contacts, can occur during the MOL stage to connect the individual components fabricated during the FEOL stage. In the BEOL stage, these components are connected to each other to distribute signals, as well as power and ground. The conductive interconnect layers serve as a network of pathways that transport signals throughout an IC, thereby connecting circuit components of the IC into a functioning whole and to the outside world. Because there typically isn't enough room on the chip surface to create all of the necessary connections in a single layer, chip manufacturers build vertical levels of interconnects. While simpler ICs can have just a few metal layers, complex ICs can have ten or more layers of wiring.

Interconnect structures close to the transistors need to be small because they attach/join to the components that are themselves very small and often closely packed together. These lower-level lines, which can be referred to as local interconnects, are usually thin and short in length. Global interconnects are higher up in the structure and travel between different blocks of the circuit. Thus, global interconnects are typically thick, long, and widely separated. Connections between interconnect levels, called vias, allow signals and power to be transmitted from one layer to the next. For example, a through-silicon via (TSV) is a conductive contact that passes completely through a given semiconductor wafer or die. In multilevel IC configurations, for example, a TSV can be used to form vertical interconnections between a semiconductor device located on one level of the IC and an interconnect layer located on another level of the IC. These vertical interconnect structures include an appropriate metal and provide the electrical connection of the various stacked metallization layers.

Interconnect structures are often formed in a stack. For example, a transistor can have a gate contact (also referred to as a CB contact) and S/D contacts (also referred to as CA contacts). The S/D contacts can extend through an interlayer dielectric (ILD) region of the IC from a metal wire or via in the BEOL metal level to metal plugs (also referred to as trench silicide (TS) contacts), which are on the S/D regions of the transistor. A conventional interconnect stack fabrication process starts with the deposition of an ILD insulating material (e.g., SiO₂) over the transistor followed by the creation of trenches in the ILD insulating material. The trenches are positioned over the portion of the transistor (source, gate, drain) to which electrical coupling will be made. The liner/barrier material is deposited within the trench, and, for S/D regions, the remaining trench volume is filled with material that will form the metal plugs (or TS contacts) using, for example, a chemical/electroplating process. The excess metal is removed to form a flat surface for subsequent processing. A cap layer can be deposited over the exposed top surface of the metal plug. This process is repeated until all portions of the interconnect structure stack have been formed.

The above-described conductive lines (i.e., metal wires and vias) in BEOL layers of a multi-level IC structures can be formed using, for example, a dual damascene process that includes depositing a dielectric material as a blanket film, lithographically patterning the dielectric material, and applying a reactive ion etched (RIE), creating both trenches and vias. The pattern is then coated by a refractory metal barrier such as Ta and TaNₓ followed by a thin sputtered metal (e.g., copper) seed layer. The seed layer allows for the electrochemical deposition (ECD) of a thick metal layer that fills up the holes. Excessive metal is removed, and the surface is planarized by chemical mechanical polishing (CMP). A thin dielectric film also known as a “cap” is deposited over the patterned copper lines. This dual damascene process is repeated at each of the higher levels built. Thermal budgets for all BEOL processes are limited by temperature sensitive structures and often do not exceed temperatures higher than 400° C. for ten minutes.

As predicted by Moore's law, semiconductor devices continue to scale down in order to improve device performance and place more transistors on the substrate. As the number of devices and circuits on a semiconductor chip increases, the BEOL interconnect wiring density and the number of metal levels also increase. The corresponding scaling of interconnect wiring structures causes an increase in the parasitic resistance (R) and capacitance (C) associated with the interconnects. The RC product is a measure of the time delay introduced into the circuitry by the BEOL structures. In order to provide a parasitic RC level that is sufficiently low to support high signal speed applications, regions of the BEOL dielectric material are formed from low-k dielectric materials having a dielectric constant of less than silicon dioxide, and the interconnect structures (e.g., wire lines and vias) can be formed from copper-containing material. A suitable BEOL dielectric for reducing interconnect capacitance is a porous organosilicate glass material (e.g., SiCOH) having a dielectric constant k down to around 2.5. In general, a material is considered ultra-low-k (ULK) when its dielectric constant (k) is less than about 2.5. The dielectric constant k value(s) that is necessary for reducing parasitic RC can be achieved in a BEOL dielectric by incorporating nanopores into the siloxane backbone network, which can be accomplished by depositing BEOL dielectric material in a plasma enhanced chemical vapor deposition (PECVD) reactor using organosilicon precursors. Further, by using ultraviolet (UV) curing processes siloxane groups in the BEOL dielectric are crosslinked and nanopores are formed. Thus, UV curing can be applied to BEOL dielectric materials to lower k, thereby offsetting at least some of the increase in capacitance caused by geometrical scaling. In addition, the UV curing process induces the cross-linking of ULK dielectrics, thus improving the mechanical and chemical strength of the dielectric.

The temperature of the substrate in an IC during an exemplary UV curing process is kept below 400° C. by design as the damage threshold for temperature-sensitive structures formed over the substrate in an IC, are typically at 385° C. At this low temperature, chemical reactions allowing efficient cross-linking of siloxane groups cannot be generated. Thus, at this low temperature, efficient temperature-based curing cannot be achieved. For an efficient UV curing process, the wavelength of UV light selected is less than about 200 nm or, equivalently, the energy of UV photons is about 6 electron-volt (eV) or higher. At this wavelength, UV light is able to initiate photochemical reactions responsible for crosslinking the siloxane groups in the SiCOH film and generating nanopores in the SICOH film. Such short-wavelength UV radiation is easily absorbed by the BEOL dielectric. A typical UV curing process lasts for several minutes.

However, the above-described UV curing processes have inefficiencies in that the ability of UV light to cure the BEOL dielectric dissipates as the UV light moves through the BEOL dielectric. As a result, after application of known UV curing processes, some regions of the BEOL dielectric (e.g. near where the UV light enters the BEOL dielectric) will be sufficiently cured, and some region of the BEOL dielectric will be partially cured, and some regions of the BEOL dielectric (e.g. near an unexposed surface of the BEOL dielectric that is opposite the surface where the UV light enters the BEOL dielectric) will be mostly cured by exposure to the substrate temperature at 385° C.

The above-described UV curing processes also introduce porosity into the BEOL dielectric. More specifically, the SiCOH material used to form the BEOL dielectric includes cross-linked SiO₂-like tetrahedral structures as the backbone and some —CH₃ or —H as the terminal groups or side chains. In the cured SiCOH films, the —CH₃ or —H terminal groups lower polarizability thereby reducing the material dielectric constant. In deposited SiCOH films, various organic groups are weakly bonded to the backbone. These weakly-bonded organic groups can be used to introduce porosity and reduce material volume density. The previously-described PECVD process used to deposit the BEOL dielectric mixes the organic precursor for sacrificial porogen (e.g., cyclohexene, and the like) and the matrix precursor for the low-k backbone structure (e.g., decamethylcyclopentasiloxane, diethoxymethylsilane, dimethyldimethoxysilane, tetramethylcyclotetrasilane, octamethylcyclotetrasilane, and the like). The previously described UV curing process potentially can remove volatile organic porogens loosely bonded to the low-k backbone. As a result, UV curing processes introduce porosity into the low-k BEOL dielectrics. While the exposure to substrate temperature at 385° C. can initiate a removal of volatile organic porogens, the efficient crosslinking and formation of a strong backbone network benefit from photochemical reactions initiated by abundant energetic UV photons.

In general, porous ULK films are known to be mechanically and chemically weaker than their non-porous low-k counterparts. For instance, Young's moduli of ULK films are in the 2-8 GPa range, depending on the degree of porosity, making ULK films used in BEOL regions of an IC especially susceptible to mechanical stresses during BEOL processing and during chip packaging.

Thus, the higher porosity and inefficient crosslinking in BEOL dielectrics as a result of UV curing weakens the BEOL dielectric layers and makes them susceptible to plasma induced damage during via etch, an increased wet etch rate of the damaged layer, and blown-out via profiles. The impact of a damaged BEOL dielectric layer becomes especially acute for smaller IC geometries. For a 7 nm node, a 2.5× increase in the thickness of a damaged ILD layer can result in a capacitance penalty of 6% negating most of the previously described benefits of having a low-k BEOL dielectric.

Turning now to an overview of aspects of the invention, embodiments of the invention address the problems associated with known methods of curing (or hardening) dielectric materials by providing a novel curing method (referred to herein as “bottom-up curing”) configured to cure a layer of dielectric material from the bottom up after the layer of dielectric material has been deposited over another layer of dielectric material. Unlike traditional UV curing process described above, this curing process is performed by short high-temperature pulses with an assistance of lower energy photons. In aspects of the invention, the novel bottom-up curing method is applied to a semiconductor structure having a second BEOL dielectric layer formed over a first BEOL or MOL dielectric layer, wherein the first BEOL or MOL layer includes conductive interconnect structures (e.g., wires and vias) formed therein. An energy source (“the second energy source”) is used to generate electromagnetic radiation and direct the electromagnetic radiation through a top surface of the second BEOL dielectric layer. In aspects of the invention, the wavelength of the electromagnetic energy is selected such that the first and second BEOL dielectric layers are nearly transparent to the electromagnetic radiation at the selected wavelength and the interconnect structures absorb the electromagnetic radiation at the selected wavelength. This results in a use of longer wavelength radiation as compared to traditional UV curing processes and correspondingly less energetic photons. Nevertheless, the selected wavelength must be short enough to be absorbed by the conductive interconnect structures in the first BEOL or MOL layer located below. The practical wavelength range for metallic BEOL/MOL interconnect structures and SiCOH-based interlayer dielectric material is from about 600 nm to about 250 nm with corresponding photon energy of from about 2 eV to about 5 eV. Accordingly, the electromagnetic radiation that is directed to the top surface of the second BEOL dielectric layer passes through the second BEOL dielectric layer and a portion of the first BEOL or MOL dielectric layer before impacting and being absorbed by the interconnect structures.

In accordance with aspects of the invention, the absorbed electromagnetic radiation quickly raises the temperature of the interconnect structures such that the interconnect structures generate heat that radiates away from the interconnect structures, back up through a portion of the first BEOL dielectric layer, through a bottom surface of the second BEOL dielectric layer, and into the second BEOL dielectric layer, thereby heating and curing at least portions of the second BEOL dielectric layer from the bottom up.

In accordance with aspects of the invention, the electromagnetic radiation is controlled such that the electromagnetic radiation quickly raises the temperature of the interconnect structures to a level that is significantly above 400° C., the damage threshold for temperature-sensitive structures formed within existing FEOL, MOL, and BEOL layers. The temperature is high enough to initiate chemical reactions necessary for efficient removal of volatile organic porogens and to initiate crosslinking within the second BEOL dielectric backbone network. In accordance with aspects of the invention, the quick rise and fall of the interconnect temperature limits any damage to the temperature-sensitive structures while allowing curing of the BEOL dielectric layer. In accordance with aspects of the invention, the increase in the temperature of the interconnect structures is controlled by controlling a duration of the exposure of the interconnect structures to the electromagnetic radiation. In accordance with aspects of the invention, the increase in the temperature of the interconnect structures is further controlled by using the second energy source to transmit the electromagnetic radiation as a train of pulses, wherein each of the pulses has a predetermined peak pulse energy density, and wherein each of the pulses has a predetermined pulse width.

In accordance with aspects of the invention, the amount of heat energy generated by the interconnect structures is controlled by controlling a duration of the exposure of the interconnect structures to the electromagnetic radiation. In accordance with aspects of the invention, the duration of the exposure of the interconnect structures to the electromagnetic radiation can be controlled by controlling the energy source to transmit the electromagnetic radiation as a train of pulses, wherein each of the pulses has a predetermined peak pulse energy density, and wherein each of the pulses has a predetermined pulse width.

In accordance with aspects of the invention, the novel bottom-up curing method can be applied prior to exposing the top surface of the second BEOL dielectric layer to a short-wavelength ultraviolet (UV) radiation employed in traditional UV curing that is absorbed by the upper regions of the second BEOL dielectric layer, and that leaves the bottom regions of the second BEOL dielectric layer substantially unchanged by the short-wavelength UV radiation.

In accordance with aspects of the invention, the novel bottom-up curing method can be applied subsequent to exposing the top surface of the second BEOL dielectric layer to short-wavelength UV radiation that is absorbed by the upper regions of the second BEOL dielectric layer, and that leaves the bottom regions of the second BEOL dielectric layer substantially unchanged by the short-wavelength UV radiation.

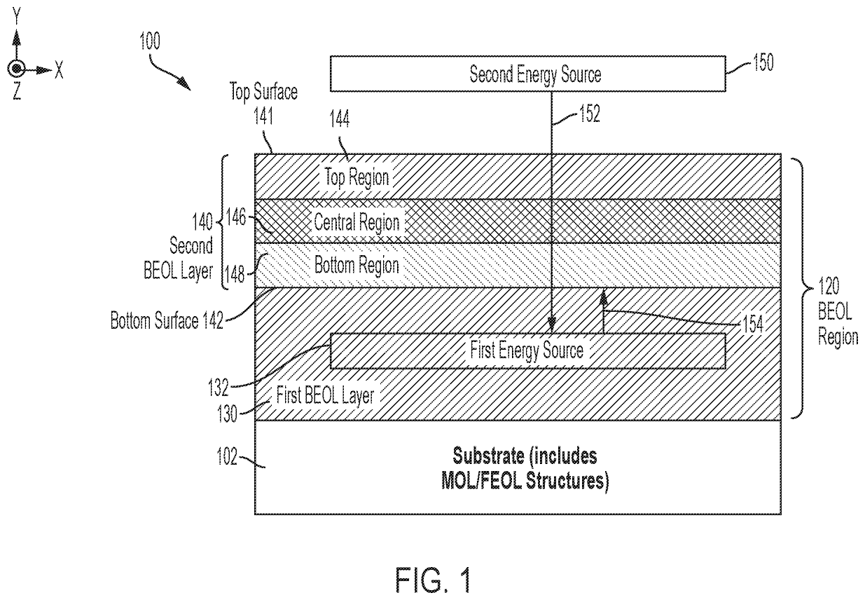

Turning now to a more detailed description of aspects of the present invention, FIG. 1 depicts a portion of an IC wafer 100 in accordance with aspects of the invention. The IC wafer 100 includes a substrate (having middle-of-line (MOL) and front-end-of-line (FEOL) structures) 102 and a BEOL region 120 formed over the substrate 102. The BEOL region includes a first BEOL dielectric layer 130 and a second BEOL dielectric layer 140, configured an arranged as shown. In aspects of the invention, the first BEOL dielectric layer 130 includes a first passive energy source 132. In accordance with aspects of the invention, the passive nature of the first energy source implies that it requires an external energy source to initiate activation. In accordance with aspects of the invention, the first passive energy source 132 can be implemented as a network of conductive interconnect structures (e.g., wires and/or vias) configured to communicatively couple semiconductor devices (i.e., MOL/FEOL structures) of the substrate 102 to one another. In accordance with aspects of the invention, if the first BEOL layer is absent, the conductive interconnect structures of the MOL layers will function as the first passive energy source 132.

In accordance with aspect of the invention, an example of the novel bottom-up curing process described herein uses a second active energy source 150 to generate electromagnetic radiation 152 and direct the electromagnetic radiation 152 into a top surface 141 of the second BEOL dielectric layer 140. In aspects of the invention, the second active energy source 150 is a laser, and the electromagnetic radiation 152 is laser light. In aspects of the invention, the wavelength of the electromagnetic radiation 152 is selected such that the first and second BEOL dielectric layers 130, 140 are nearly transparent to the electromagnetic radiation 152 at the selected wavelength and the first energy source 132 absorbs the electromagnetic radiation 152 at the selected wavelength. The practical wavelength range for metallic BEOL/MOL interconnect structures and SiCOH-based interlayer dielectric material is from about 600 nm to about 250 nm with corresponding photon energy of from about 2 eV to about 5 eV. Accordingly, the electromagnetic radiation 152 passes through the second BEOL dielectric layer 140 and a portion of the first BEOL dielectric layer 130 before impacting and being absorbed by the first passive energy source 132. The electromagnetic radiation 152 that is absorbed by the first passive energy source 132 quickly raises the temperature of the first energy source 132 such that the first energy source 132 is activated generating heat 154 that radiates away from the first energy source 132, back up through a portion of the first BEOL dielectric layer 130, through a bottom surface 142 of the second BEOL dielectric layer 140, and into the second BEOL dielectric layer 140, thereby curing at least portions of the second BEOL dielectric layer 140 from the bottom surface 142 up. The various levels of curing in the second BEOL dielectric layer 140 that result from the heat 154 are represented by the bottom region 148, the central region 146, and the top region 144. In accordance with aspects of the invention, the characteristics of the electromagnetic energy 152 are controlled such that the heat 154 cures the bottom region 148 to a first level of curing, cures the central region 146 to a second level of curing, and cures the top region 144 to a third level of curing, wherein the first level of curing is greater than the second level of curing, and wherein the second level of curing is greater than the third level of curing. In some aspects of the invention, the characteristics of the electromagnetic radiation 152 are controlled such the third curing level is substantially zero.

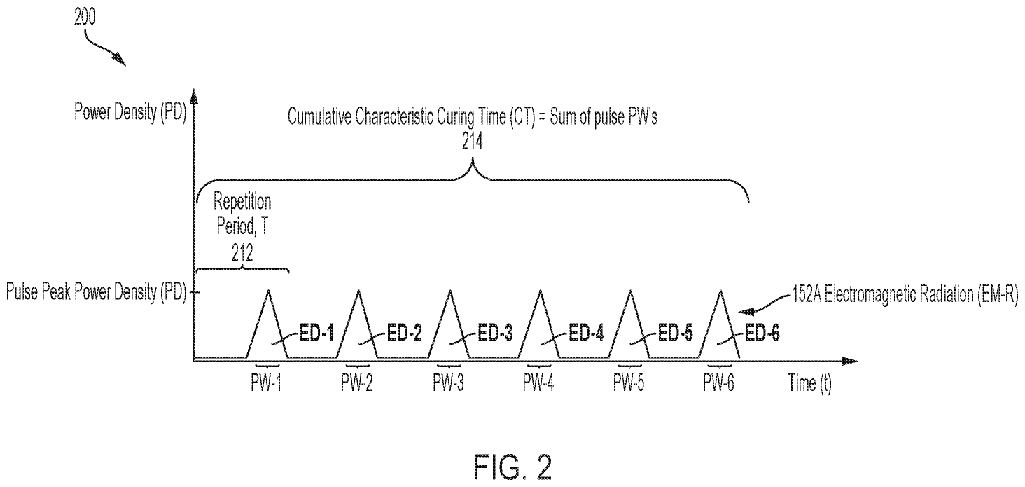

FIG. 2 depicts a diagram 200 illustrating how the electromagnetic radiation 152 (shown in FIG. 1) can be implemented as a sequence of electromagnetic radiation pulses 152A configured in accordance with aspects of the invention. The electromagnetic radiation 152A has a wavelength (W) selected in accordance with aspects of the invention as described above. As shown in FIG. 2, the diagram 200 is a plot of the power density (PD) or intensity of the electromagnetic radiation 152A over time (t) for a selected cumulative curing exposure time (CT) 214. Each pulse of electromagnetic radiation 152A is defined by a pulse shape. The pulse shape can be characterized by a peak power density (PD) and a pulse width (PW). For pulses with gaussian or bell-curve shapes, the pulse width (PW) is measured at full width at half maximum (FWHM). The pulse energy density (ED) is the integral of its power density over time, which can be used to characterize individual pulses as a metric alternative to the power density. Pulse repetition period (T) 212 is typically much longer than the individual pulse width. Cumulative curing exposure time (CT) 214 can be defined as a sum of pulse widths for individual pulses of same/similar energy density.

In aspects of the invention, the electromagnetic radiation 152/152A can be implemented by controlling the laser light. The wavelength of the laser light can be selected at around 532 nm, 355 nm, 351 nm, 308 nm, or 248 nm using commonly available laser sources. Frequency-doubled or -tripled solid-state Nd: YAG laser can be used for 532 nm or 355 nm laser light, respectively. Excimer lasers can be used for laser light at 248 nm (KrF excimer), 308 nm (XeCl excimer), and 351 nm (XeF excimer) wavelength. Excimer lasers are usually operated in a Q-switched, pulsed mode with a typical pulse width PW of from 0.1 ns to 100's ns and their repetition period (T) 212 of from 1 microsecond (μs) to 1 second (s). The beam of excimer laser is shaped to expose a small portion of substrate surface (e.g. one die) with a target power or energy density. The number of pulses of radiation train 152A can be programmed by re-exposing the same substrate area with multiple laser pulses. The entire substrate is processed in a step-and-repeat exposure pattern. Solid-state Nd: YAG lasers can be configured in continuous, pulsed, or Q-switched pulsed modes suitable for both raster scanning and step-and-repeat pulsed operation. The pulsed operation of solid-state Nd: YAG lasers is similar to that of excimer lasers. The substrate laser scanning exposure pattern employs a focused laser beam that is quickly scanned over the substrate surface. The pulse width PW for the raster scanning approach is defined by the beam width in the scanning direction and the scanning velocity and is typically from about 10's ns to over 1 microsecond (μs). The number of radiation pulses 152A can be programmed by scanning the same substrate area multiple times.

Referring now to FIGS. 1 and 2, in accordance with aspects of the invention, the electromagnetic radiation 152A is controlled such that the electromagnetic radiation 152A raises the temperature of the first energy source 132 to a level that is significantly above 400° C. The temperature is high enough to initiate chemical reactions necessary for efficient removal of volatile organic porogen and to initiate crosslinking within the second BEOL dielectric backbone network. In accordance with aspects of the invention, a typical temperature level to which the first energy source 132 is raised is from about 1000° C. to about 1300° C. Often this level is limited by the melting temperature of the conductive metal employed in the first energy source 132. The target temperature can exceed the melting point of 132, however, according to the embodiments of the invention, it is always maintained within 200° C. of the melting temperature of the first energy source 132, to avoid excessive overheating of the molten phase. For example, in some aspects of the invention, the first energy source 132 can be implemented as a network of conductive interconnect structures (e.g., copper wires and/or vias) configured to communicatively couple semiconductor devices (i.e., MOL/FEOL structures) of the substrate 102 to one another. In accordance with aspects of the invention, the target temperature level of the first energy source 132 is from 1000° C. to about 1287° C. whereas the melting point of copper is 1087° C. In accordance with aspects of the invention, the increase in the temperature of the first energy source 132 is controlled by controlling each of the pulses to have a predetermined pulse width (PW) and energy density (ED).

In accordance with aspects of the invention, the amount of heat energy 154 generated by the first energy source 132 is controlled by controlling a duration of the exposure of the first energy source 132 to the electromagnetic radiation 152A. In accordance with aspects of the invention, the duration of the exposure of the first energy source 132 to the electromagnetic radiation 152A can be controlled by controlling the predetermined pulse width (PW).

In accordance with aspects of the invention, the novel bottom-up curing method described herein can be applied prior to exposing the top surface 141 of the second BEOL dielectric layer 140 to conventional UV curing using a short-wavelength radiation that is absorbed by the second BEOL dielectric layer 140 such that the top region 144 is UV-cured to a first UV-curing level, the central region 146 is UV-cured to a second UV-curing level, and the bottom region 148 is UV-cured to a third UV-curing level. Using known UV curing methods and based on the thickness of the second BEOL dielectric layer 140, the first level of UV-curing is greater than the second level of UV-curing, and the second level of UV-curing is greater than the third level of UV-curing. A shortcoming of known UV-curing methods, which is overcome by the novel bottom-up curing method described herein, is that the third UV-curing level is substantially zero.

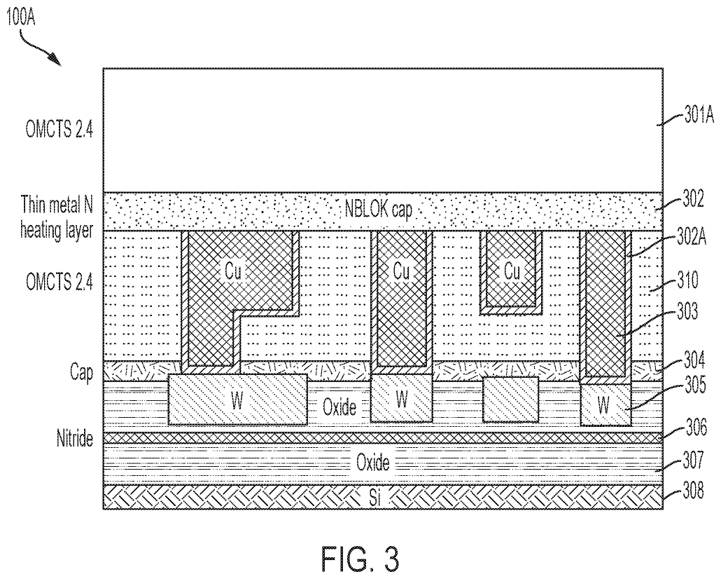

FIGS. 3-6 depict the results of fabrication operations for forming IC structures 100A, 100B, 100C, 100D in accordance with aspect of the invention. In FIG. 3, known fabrication operations have been used to form the multi-layered IC wafer 100A. A variety of well-known fabrication operations are suitable for forming the multi-layered IC wafer 100A to the fabrication stage shown in FIG. 3. Accordingly, in the interest of brevity, such well-known fabrication operations are either omitted or described and illustrated at a high level. As shown in FIG. 3, known fabrication operations have been used to form a substrate 308 having MOL & FEOL structures 307, 306, 305 and 304 formed therein or thereon. Fabrication operations such as wafer preparation, isolation, and gate patterning have been used to form the FEOL structures, which can include structures such as wells, S/D regions, extension junctions, silicide regions, liners, and the like. The MOL structures include contacts and other structures that couple to the active regions (e.g., gate/source/drain) of the FEOL structures.

Referring still to FIG. 3, BEOL interconnect structures (i.e., metallization levels) 303 can be formed using a dual damascene process in which openings/trenches are etched in a dielectric layer (e.g., ILD 301E) and filled with metal to create metallization levels (e.g., interconnect elements) of the BEOL interconnect structures 303. More specifically, known fabrication operations have been used to form a liner/cap layer 302 over the metallization layer 303 in a low-k ILD layer/region 301E as part of the BEOL structures formed during initial portions of the BEOL fabrication stage. The interconnect structures 303 can vary in dimensions depending upon the specification and requirement of the IC 100A. In aspects of the invention, the interconnect structures 303 can be a conductive metal such as copper, cobalt, and the like. In aspects of the invention, the ILD region 301E can be formed from a low-k dielectric (e.g., k less than about 4), an ultra-low-k (ULK) dielectric (e.g., k less than about 2.5), and the like. A cap layer 302 (e.g., SiN or SiNCH) has been deposited over the ILD 301E and the interconnect structures 303. A low-k ILD region 301A has been deposited over the cap 302. The metallization layer 303 features of liners 302A that surround the metal vias 303. The liner 302A functions as a barrier to prevent metals in the interconnect structures 303 from migrating into the ILD region 301E. Additionally, the cap layer 302 can provide adhesion between the interconnect structures and ILD region.

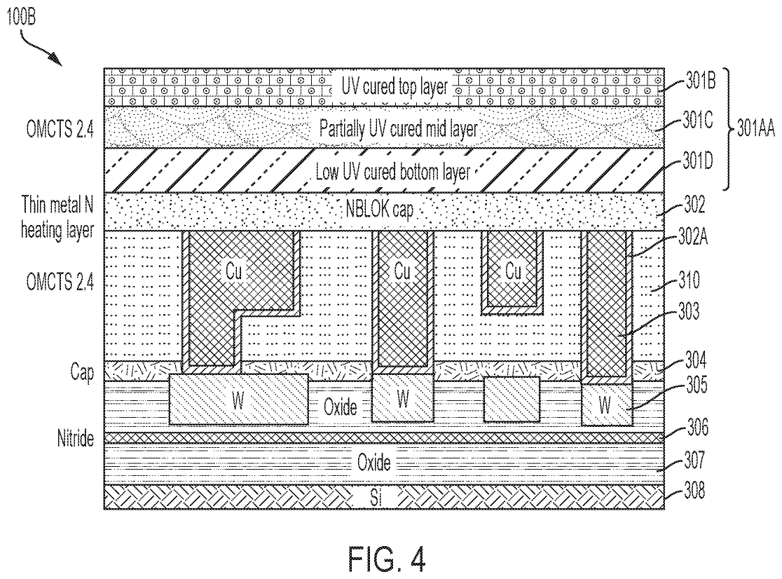

FIGS. 4-6 depict a curing process in which the novel bottom-up curing method is applied after conventional UV curing process. In FIG. 4, a first conventional UV curing process has been applied to the low-k dielectric film to form a desired porosity level of the material and to enhance the chemical and mechanical properties of the BEOL dielectric layer. The UV cured dielectric layer 301AA can be roughly divided into three sections, 301B which is the top region with a top region backbone network strength, a central layer 301C with a central region backbone network strength and a bottom layer 301 D with a bottom region backbone network strength. The film porosity will be nearly uniform throughout regions 300B, 300C, 301D and is determined by amount and type of porogens present in an as-deposited film 301A (FIG. 3). It is also governed by the substrate temperature level during UV curing process (typically at 385° C.). During conventional UV curing, the applied short-wavelength UV radiation passes through the dielectric layer and as a result of subsequent absorption by the dielectric layer, the intensity of the UV radiation attenuates through the dielectric layer. Accordingly, the top region 301B is exposed to a high level of UV radiation intensity, the central region 301C is exposed to a medium level of UV radiation intensity, and the bottom region 301D is exposed to a low level of UV radiation intensity. This results in a varying degree of backbone network strength in the dielectric layer as indicated above and schematically labeled in FIG. 4 as “UV-cured” for the top region 301B, “partially UV-cured” for the mid region 301C, and “low UV-cured” for the bottom region 301D. FIG. 4 schematic illustrates a varying degree of effectiveness of conventional UV curing processes.

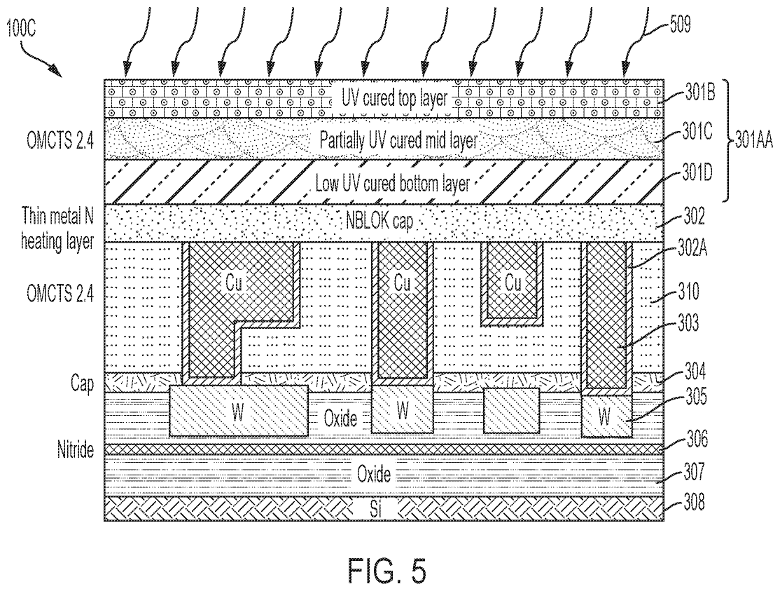

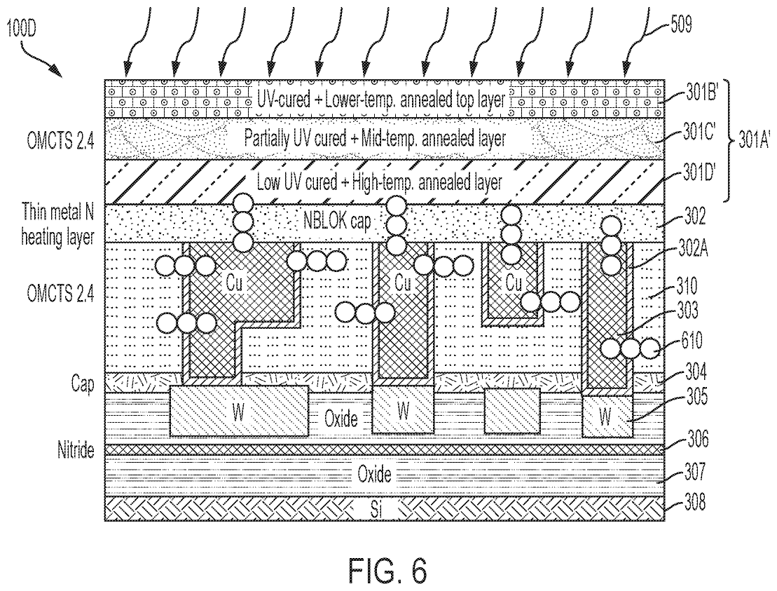

A novel curing process in accordance with the aspects of the invention can be implemented as depicted in FIGS. 5-6. The curing process includes using a second energy source to generate electromagnetic radiation 509 to activate the first energy source 303 such that secondary heat energy 610 is generated by the first energy source 303. This high-energy-density electromagnetic radiation 509 is applied for a short duration and it results in an improved strength of the dielectric backbone network. Accordingly depicted in layers 301B′, 301C′ and 301D′. According to embodiments of the invention, the novel curing process equalizes the backbone network strength throughout the dielectric layer.

A robust curing process in accordance with the aspects of the invention can be implemented as depicted in FIG. 6. Electromagnetic radiation 509 generated from a second energy source passes through the dielectric layer 301A′. The predetermined radiation wavelength (W) of 509 is such that the dielectric layer 301A′ is unable to absorb the electromagnetic radiation 509. The first energy source 303 absorbs the electromagnetic radiation 509 as primary energy and emits secondary energy 610 in the form of heat. After the novel curing process, the dielectric film 301A′ can be roughly divided into the bottom region 301D′ that received the highest amount of heat energy 610 and accordingly annealed at a highest temperature, the central region 301C′ that received lesser heat energy 610 as compared to 301D′ and is accordingly annealed at a medium temperature, lower than that of 301D′, and the top region 301B′ that received the least amount of heat energy 610 as compared to 301C′ and 301D′, and it is accordingly annealed at a temperature lower than that of 301C′ and 301D′. In accordance with the aspects of the invention, the radiation pulse width (PW), see FIG. 2, can be used to control the differences in heat energies received by regions 301B′, 301C′, 301D′ and accordingly the differences in their respective anneal temperatures.

In accordance with the aspects of the invention, and still referring to FIG. 6 and FIG. 2, the radiation pulse energy density (ED), can be used to control the absolute amount of heat energy received by region 301D′ and accordingly control its peak anneal temperature. In accordance with the aspects of the invention, the radiation pulse energy density (ED) is from about 0.01 J/cm² to 10 J/cm² yielding the peak anneal temperature range of about 1000° C. to about 1300° C. The selection of radiation pulse energy density (ED) depends on the substrate reflectance at the predetermined radiation wavelength (W), the relative amount of electromagnetic radiation 509 absorbed by the first energy source 303, the respective thermal properties of energy source 303, BEOL dielectric layers 310 and 302, and substrate/MOL structures 304-308 (e.g. their respective thermal conductivity, thermal diffusivity, and thermal interfacial resistances), and the radiation pulse width (PW). In accordance with the aspects of the invention, the pulse width (PW) is typically from about 1 nanosecond (ns) to about 1 microsecond (μs). Such short pulse width used according to embodiments of the invention, protects temperature-sensitive structures present throughout the IC structure and it also induces a thermal gradient in the film 301A′ such that the region 301C′ is annealed at a temperature that is 10-200° C. lower than the region 301D′, and the region 301B′ is annealed at a temperature that is 10-200° C. lower than the region 301C′.

Referring still to FIGS. 5-6, exposure of film 301AA to high-temperature pulses induces chemical changes in the dielectric film. The amount of chemical changes is exponentially dependent on the peak anneal temperature leading to different material properties in the regions 301B′, 301C′, and 301D′. Specifically, a higher anneal temperature results in effective crosslinking of siloxane groups, thereby strengthening the dielectric backbone network. Very high-temperatures above 1200° C. results in the collapse of existing pores leading to a lower porosity in the dielectric layer, however, such extreme regime is not desirable due to a substantial increase in the dielectric constant. On the other hand, a short temperature radiation pulse is inefficient in inducing additional backbone network crosslinking within the film 301AA. This behavior can be attributed as result of exposure to an ultra-short duration of the radiation pulse at high temperature. According to the embodiments of the invention, multiple radiation pulses, see FIG. 2, are used to enhance high-temperature curing of film 301AA. The cumulative curing exposure time (CT) 214 of the multiple radiation pulses is proportional to the cumulative annealing duration. For instance, a train of ten radiation pulses with each pulse width of 100 ns will have the cumulative curing exposure time (CT) 214 of 1 microsecond and the cumulative annealing duration at high temperature (within 50° C. of the peak) of about 300 ns. The cumulative annealing duration of multiple short pulses is not the same as the equivalent annealing duration by a single, long-duration radiation pulse. A single long pulse is known to cause thermal damage to adjacent temperature-sensitive structures while multiple short pulses preserve temperature-sensitive structures while enabling higher degree of network backbone crosslinking within film 301AA.

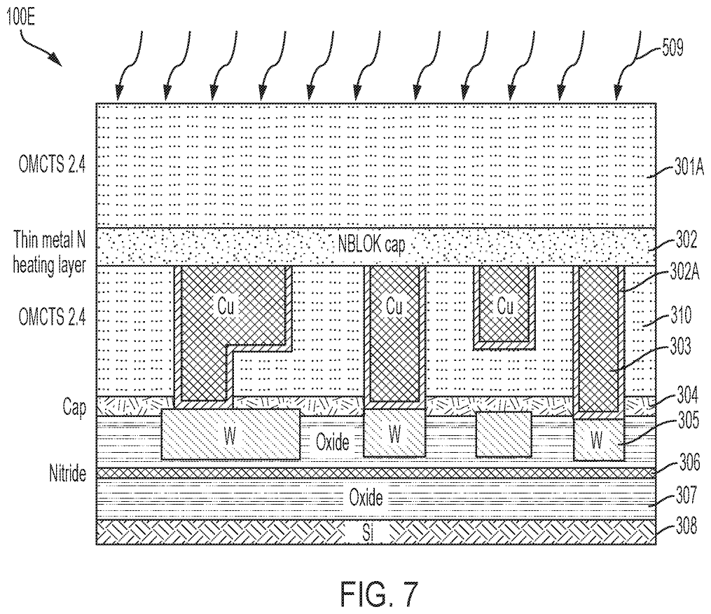

FIGS. 7-9 depict a curing process in which the novel bottom-up curing method is applied prior to a conventional UV curing process. In FIG. 7, a novel curing process is first applied to an as-deposited dielectric film 301A in accordance with the aspects of the invention.

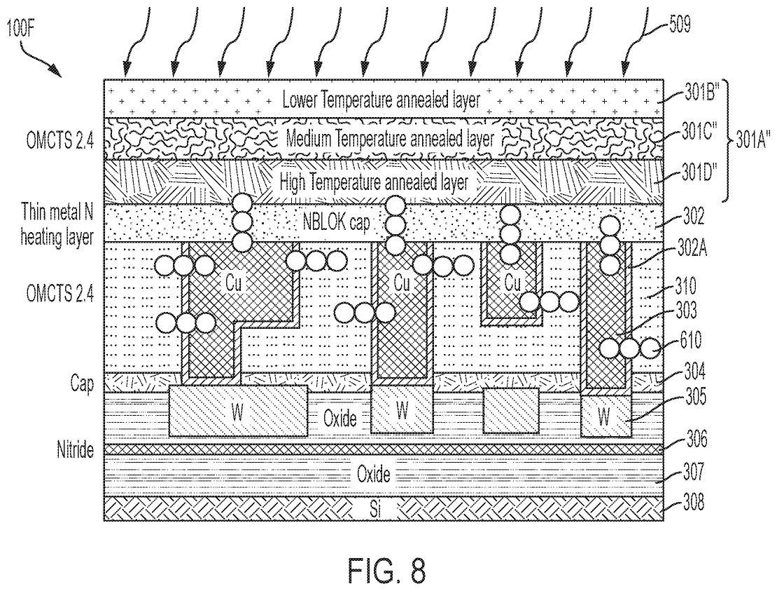

A robust curing process in accordance with the aspects of the invention can be implemented as depicted in FIG. 8. An electromagnetic radiation 509 from a second energy source passes through the dielectric layer 301A″. The predetermined radiation wavelength (W) of 509 is such that the dielectric layer 301A″ is unable to absorb this radiation 509. On the other hand, the first energy source 303 absorbs electromagnetic radiation 509 as primary energy and emits secondary energy 610 in the form of heat. After the novel curing process, the dielectric film 301A″ can be roughly divided into three layers. The bottom region 301D″ received the highest amount of heat energy 610 and accordingly annealed at a highest temperature, the central region 301C″ received lesser heat energy 610 as compared to 301D″ and accordingly annealed at a medium temperature, such that the annealing temperature of 301C″ is lower than that of 301D″, and the top region 301B″ received the least amount of heat energy 610 as compared to 301C″ as well as 301D″ and accordingly annealed at a lowest temperature, such that the annealing temperature of 301B″ is lower than that of film 301C″ as well as 301D″.

In accordance with the aspects of the invention, and still referring to FIG. 8 and FIG. 2, the radiation pulse width (PW), can be used to control the differences in heat energies received by regions 301B″, 301C″, 301D″ and accordingly the differences in their respective anneal temperatures. In accordance with the aspects of the invention, the radiation pulse energy density (ED), see FIG. 2, can be used to control the absolute amount of heat energy received by region 301D″ and accordingly its peak anneal temperature. In accordance with the aspects of the invention, the radiation pulse energy density (ED) is from about 0.01 J/cm² to 10 J/cm² yielding the peak anneal temperature range of region 301D″ of from about 1000° C. to about 1300° C. The selection of radiation pulse energy density (ED) depends on the substrate reflectance at the chosen radiation 509 wavelength (W), the relative amount of radiation absorbed by the first energy source 303, the respective thermal properties of energy source 303, BEOL dielectric layers 310 and 302, and substrate/MOL structures 304-308 (e.g. their respective thermal conductivity, thermal diffusivity, and thermal interfacial resistances), and the radiation pulse width (PW). In accordance with the aspects of the invention, the pulse width (PW) is typically from about 1 nanosecond (ns) to about 1 microsecond (um). Such short pulse width used according to embodiments of the invention, protects temperature-sensitive structures throughout the IC structure and it also induces a thermal gradient in the film 301A″ such that the region 301C″ is annealed at a temperature that is 10-200° C. lower than 301D″ and the region 301B″ is annealed at a temperature that is 10-200° C. lower than the region 301C″.

Referring still to FIGS. 7-8, exposure of film 301A to high-temperature pulses induces chemical changes in the BEOL dielectric film. The amount of chemical changes is exponentially dependent on the peak anneal temperature leading to different material properties in the regions 301B″, 301C″, and 301D″. Specifically, a higher anneal temperature results in effective removal of porogen groups leading to a higher porosity and, at the same time, effectively crosslinking siloxane groups, thereby strengthening the dielectric backbone network. Very high temperatures above 1200° C. result in the collapse of existing pores leading to a lower porosity in the dielectric layer, however, such extreme regime is not desirable due to a substantial increase in the dielectric constant. On the other hand, a short temperature pulse is also inefficient in resulting chemical transformations within film 301A due to an ultra-short duration of high temperature. According to the embodiments of the invention, multiple radiation pulses, see FIG. 2, can be used to enhance curing of film 301A. The cumulative curing exposure time (CT) 214 of multiple radiation pulses is proportional to the cumulative annealing duration. For instance, a train of ten radiation pulses with each pulse width of 100 ns will have the cumulative curing exposure time (CT) 214 of 1 microsecond and the cumulative annealing duration at high temperature (within 50° C. of the peak) of about 300 ns. The cumulative annealing duration of multiple short pulses is not the same as the equivalent annealing duration by a longer radiation pulse. A single long pulse is known to cause thermal damage to adjacent temperature-sensitive structures within the IC, while multiple short pulses preserve temperature-sensitive structures within the IC while further enabling a more complete chemical transformation in dielectric layer 301A″. Nevertheless, the regions of film 301A″ may or may not be fully cured by multiple high-temperature pulses due to overall shortness of the curing process.

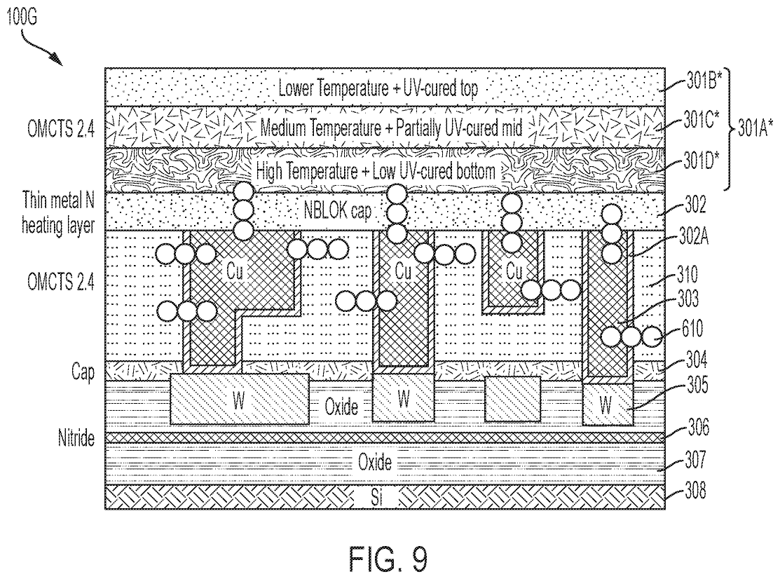

In FIG. 9, a conventional UV curing process has been applied to film 301A″ to complete its chemical transformation resulting in a film 301A*. The conventional UV curing process is conducted at the substrate temperature below 400° C. (typically at 385° C.) for several minutes. This process removes the detached porogen groups while the short-wavelength of UV radiation allows for additional crosslinking of siloxane groups thereby further strengthening the dielectric layer. The BEOL dielectric film's final porosity distribution is set by both the novel high-temperature pulsed annealing conducted in a prior step and the conventional UV curing process as depicted in FIGS. 7-9. The applied short-wavelength UV radiation passes through the dielectric film and its intensity attenuates due to film absorption. Accordingly, the top region 301B* is exposed to a high level of UV radiation intensity, the central region 301C* is exposed to a medium level of UV radiation intensity, and the bottom region 301D* is exposed to a low level of UV radiation intensity. The porosity and backbone network crosslinking in the bottom region 301D* is mainly set by the high-temperature pulsed annealing and is slightly further modified by conventional UV curing process. The porosity and backbone network crosslinking in the top region 301B* is mainly set by conventional UV curing process, but also is further positively affected by high-temperature pulsed annealing. The porosity and backbone network crosslinking in the central region 301C* is set by both high-temperature pulsed annealing and conventional UV curing process. This leads to a level of porosity that is lower in the bottom region 301D* than the levels of porosity in regions 301B* and 301C* and an improved backbone network crosslinking throughout three regions 301B*, 301C*, and 301D* of the BEOL dielectric film 301A*. The benefit of the combination of the novel high temperature annealing with the conventional UV curing is much appreciated for smaller IC geometries.

Curing processes in which the novel bottom-up curing method is applied prior to a conventional UV curing process (depicted in FIGS. 7-9) and in which the novel bottom-up curing method is applied after a conventional UV curing process (depicted in FIGS. 4-6) result in different chemical transformations in the dielectric film 301A and lead to a different material properties of resultant cured films 301A′ and 301A*. Furthermore, the curing sequence depicted in FIGS. 4-6 can be applied after the curing sequence depicted in FIGS. 7-9 for an additional benefit.

The following examples illustrate aspects of the present invention but are not intended to limit the scope of the invention. The examples of the instant invention demonstrate that inventive process results in the formation of a laser hardened film that is a completely cured dielectric film and is more etch resistant than a film formed by UV curing alone.

### EXAMPLES

Nanosecond-scale laser annealing were performed on flowable SiCOH (FCVD SiCOH) film with k of ˜2.8 and PECVD porous SiCOH film with k of ˜2.55-2.6 and compared to a PECVD SiCOH film with k of ˜2.77-2.85. Laser annealing was conducted either before UV curing (“laser first”) or after (“laser last”). Porous PECVD “SiCOH 2.55” and FCVD SiCOH films were UV cured at 385° C. for several minutes. Low-porosity “SiCOH 2.7” film does not require any additional UV cure. Laser annealing employed a 308 nm XeCl excimer laser with a pulse width of ˜160 ns and repetition period of ˜0.1 s. The laser energy density was carefully chosen so that the peak dielectric temperature was just above the Cu melt point of 1085° C. for both blanket dielectric films on Si substrates and the M1 ILD film on tungsten M0 structures. For RC delay measurements, laser treatments were conducted for M1 ILD layer only to exclude any laser-induced resistive effects of Cu wire. The blanket dielectric parameters were measured on ILD films on Si substrates. Porosity was extracted using ellipsometry porosimetry. The plasma induced damage (PID) wet etch resistance was evaluated using the delta thickness method.

The key blanket properties of the BEOL ILD films are displayed in Table I. UV-cured FCVD SiCOH is more porous than the “SiCOH 2.7” film with comparable k and has the worst PID resistance along with the lowest C content. PID resistance and the k value were re-assessed for “SiCOH 2.55” film cured with the assistance of high-temperature, short-pulse laser anneal films post laser anneal. The PID resistance of “SiCOH 2.55” film cured by “laser first” scheme was improved to 0.13 matching that of “SiCOH 2.7” film but its k was only 2.62. The “laser first” annealing approach did not alter the bulk carbon content of the films. The PID resistance of “SiCOH 2.55” film cured by “laser last” scheme was marginally improved to 0.165 but its k was equal to that of the reference “SiCOH 2.55” film cured by UV-cure only. The “laser last” annealing approach also did not alter the bulk carbon content of the films.

TABLE I
Blanket property of BEOL ILDs

| Blanket | SiCOH 2.7 | | |
|---|---|---|---|
| property | (Industry | SiCOH | FCVD |
| measured | standard) | 2.55 | SiCOH |
| k @ 150 C. | 2.77-2.85 | 2.55-2.6 | 2.78-2.8 |
| Bulk | | | |
| Porosity by | 6.5 | 18 | 11 |
| EP (%) | | | |
| PID | 0.13 | 0.17 | 0.75 |
| Atomic % C | 32 | 28 | 17-19 |

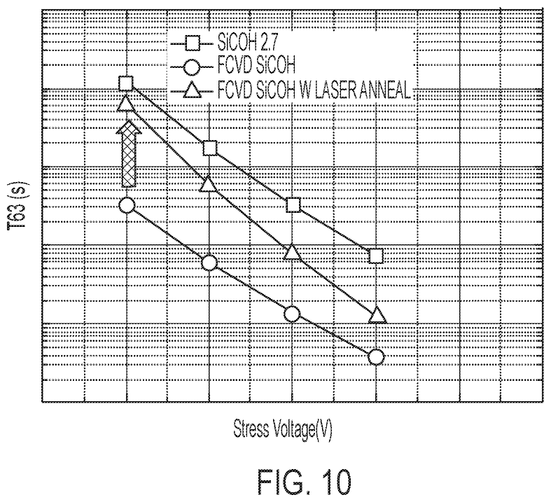

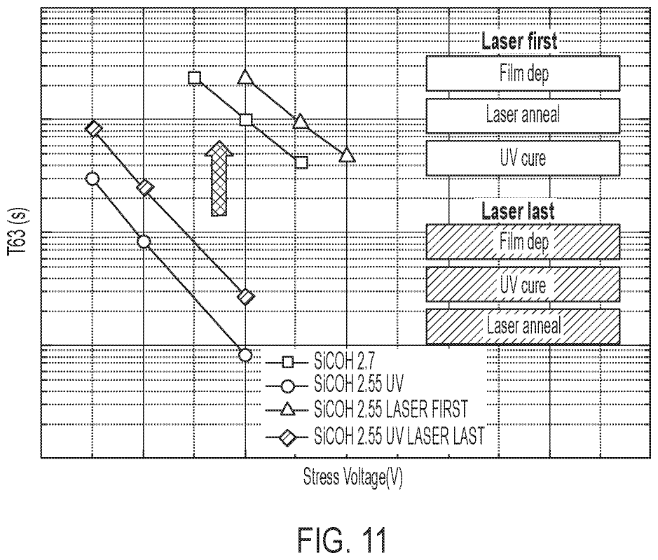

The effectiveness of the novel bottom-up, high-temperature, short-duration curing scheme was evaluated using interconnect structures with geometrical dimensions suitable for 7 nm technology node. Dielectric breakdown of via-to-adjacent-wire can be employed to assess the via profile blow-up and. This type of dielectric breakdown is known as the via Time Dependent Dielectric Breakdown or via TDDB. Accordingly, an interconnect technology with a chemically weak interlayer dielectric will result in unpredictably enlarged or blown-up via profiles reducing dielectric spacing to adjacent wires and shortening the TDDB lifetime. The via TDDB lifetime is assessed by measuring the breakdown failure rates for numerous via-to-wire structures, representing the failure rates as Weibull failure distribution, and outputting lifetime at 63rd percentile of Weibull distribution commonly known as the T63 lifetime. The “laser first” annealed FCVD SiCOH film showed a ˜10× improvement in T63 lifetime making it roughly equivalent to that of “SiCOH 2.7” film (FIG. 10). A ˜100× improvement in T63 lifetime was observed in the case of “SiCOH 2.55” film treated with the “laser first” cure scheme while the “laser last” scheme resulted in a smaller improvement (FIG. 11). This is consistent with the blanket properties and provides an insight into the origin of laser-induced hardening. The UV cure process prior to the laser treatment sets a target porosity and benchmark crosslinking while high-temperature laser annealing slightly improves crosslinking with a minor effect on the porosity and k. Laser treatment prior to UV cure sets up a lower porosity with different crosslinking. In this case, the net gain in ILD strength exceeds any degradation in porosity and k resulting in a fundamental advantage within robustness-performance tradeoff.

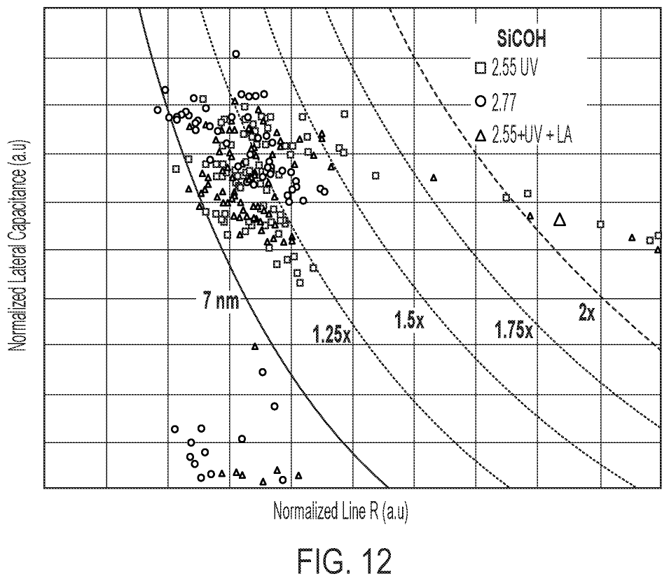

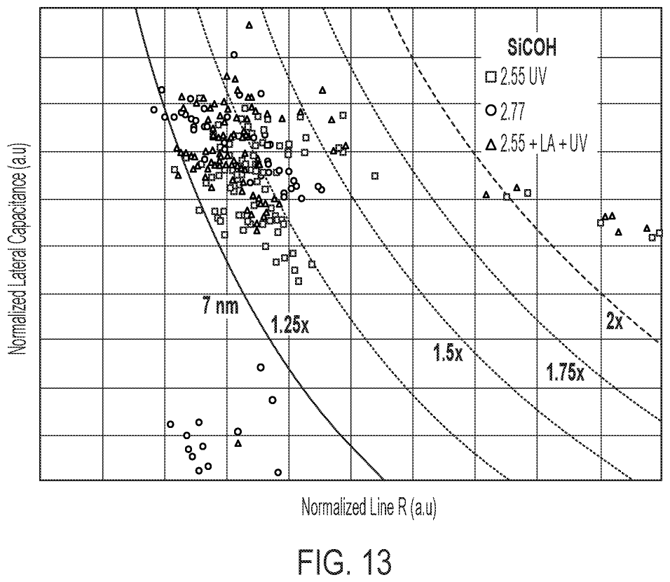

In FIGS. 12 and 13, the lateral capacitance is plotted against the line resistance for laser-annealed “SiCOH 2.55” and benchmark “SiCOH 2.7” films. This type of plot is known is the interconnect RC-delay chart. While the exact geometrical features of interconnects can vary leading to a scatter of R and C data, the RC delay product typically stays constant clustering along constant RC lines or envelopes in this chart. A fundamental advance in interconnect materials will be represented as a shift to a lower RC envelope in this chart. FIG. 12 demonstrates that the “laser last” treatment on “SiCOH 2.55” film yielding no increase in RC delay compared to UV-cured “SiCOH 2.55” film and providing 12% advantage over the benchmark “SiCOH 2.7” film. FIG. 13 demonstrates that the “laser first” treatment on “SiCOH 2.55” film yielding small degrade in RC delay due to slightly higher k but still provides ˜6% advantage over the benchmark “SiCOH 2.7” film. Comparing to the data shown in FIG. 11, one can conclude that curing of “SiCOH 2.55” by the novel bottom-up, high-temperature, short-pulse “laser first” scheme provides 6% RC-delay advantage while preserving or exceeding via TDDB of the benchmark “SiCOH 2.7” film.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

1. A method of forming a multi-layer integrated circuit (IC) structure, the method comprising:
forming a passive energy source comprising a conductive metal;
forming a target layer over the conductive metal, wherein the target layer comprises a dielectric material;
using an active energy source to generate electromagnetic radiation having a predetermined wavelength;
wherein the dielectric material is substantially transparent to the electromagnetic radiation at the predetermined wavelength;
using the active energy source to expose the conductive metal to the electromagnetic radiation by transmitting the electromagnetic radiation at the predetermined wavelength into and through the dielectric layer to impact the conductive metal for a predetermined duration;
wherein the conductive metal substantially absorbs the electromagnetic radiation at the predetermined wavelength;
wherein the conductive metal is configured to, based at least in part on being exposed to the electromagnetic radiation:
absorb the electromagnetic radiation;
experience a conductive metal temperature increase such that the conductive metal generates heat energy; and
emit the heat energy to the dielectric material; and
using the active energy source to control the electromagnetic radiation in a manner that controls the heat energy such that the heat energy follows a predetermined periodic pattern of rising to a first heat amount for a first duration and falling to a second heat amount for a second duration;
wherein the first heat amount and the first duration are sufficient to cure at least a portion of the target layer;
wherein the first heat amount is also above a level that would, if applied for a third duration, damage temperature-sensitive structures in the IC structure;
wherein the first duration is less than the third duration; and
wherein second heat amount is below the level that would, if applied for the third duration, damage the temperature-sensitive structures in the IC structure.

2. (canceled)

3. (canceled)

4. (canceled)

5. (canceled)

6. The method of claim 1, wherein the first heat amount is within ±200° C. of a melting temperature of the conductive metal.

7. The method of claim 1, wherein the target layer comprises an upper target layer region and a lower target layer region.

8. The method of claim 7 further comprising, prior to using the active energy source to expose the conductive metal to the electromagnetic radiation, exposing the dielectric material to ultraviolet (UV) radiation such that:
the UV radiation is sufficient to cure the upper target layer region; and
the UV radiation is not sufficient to cure the lower target layer.

9. The method of claim 7 further comprising, subsequent to using the active energy source to expose the conductive metal to the electromagnetic radiation, exposing the dielectric material to ultraviolet (UV) radiation such that:
the UV radiation is sufficient to cure the upper target layer region; and
the UV radiation is not sufficient to cure the lower target layer.

10. (canceled)

11. A method of forming a multi-layer integrated circuit (IC) structure, the method comprising:
forming a substrate;
forming a first IC layer above the substrate, wherein the first IC layer comprises a network of interconnect structures comprising conductive material, wherein the network of conductive material is configured to communicatively couple electronic devices of the IC structure to one another;
forming a second IC layer above the first IC layer, wherein the second IC layer comprises a porous dielectric material, wherein the second IC layer further comprises a top surface and a bottom surface;
using an electromagnetic energy source to generate electromagnetic radiation having a predetermined wavelength;
wherein the dielectric material of the second IC layer material is substantially transparent to the electromagnetic radiation at the predetermined wavelength; and
using the electromagnetic energy source to expose the network of conductive material to the electromagnetic radiation by transmitting the electromagnetic radiation into and through the second IC layer to impact the network of conductive material;
wherein the network of conductive material is configured to, based at least in part on being exposed to the electromagnetic radiation:
absorb the electromagnetic radiation;
experience a conductive material temperature increase such that the conductive metal generates heat energy; and
emit the heat energy to and through the bottom surface of the second IC layer;
using the electromagnetic energy source to control the electromagnetic radiation in a manner that controls the heat energy such that the heat energy follows a predetermined pattern of periodically rising to a first heat amount for a first duration and falling to a second heat amount for a second duration;
wherein the first heat amount and the first duration are sufficient to cure at least a portion of the first IC layer;
wherein the first heat amount is also above a level that would, if applied for a third duration, damage temperature-sensitive electronic structures included among the electronic devices of the IC structure;
wherein the first duration is less than the third duration; and
wherein second heat amount is below the level that would, if applied for the third duration, damage the temperature-sensitive electronic structures.

12. (canceled)

13. The method of claim 11, wherein the first heat amount is within ±200° C. of a melting temperature of the conductive material.

14. The method of claim 11, wherein the first IC layer comprises an upper first IC layer region and a lower first IC layer region.

15. The method of claim 14 further comprising:
prior to using the electromagnetic energy source to expose the network of conductive material to the electromagnetic radiation, exposing the top surface of the second IC layer to ultraviolet (UV) radiation such that:
the UV radiation is sufficient to substantially cure the upper first IC layer region; and
the UV radiation is not sufficient to substantially cure lower first IC layer region.

16. The method of claim 14 further comprising:
subsequent to using the electromagnetic energy source to expose the network of conductive material to the electromagnetic radiation, exposing the top surface of the second IC layer to ultraviolet (UV) radiation such that:
the UV radiation is sufficient to substantially cure the upper first IC layer region; and
the UV radiation is not sufficient to substantially cure lower first IC layer region.

17. A multi-layer integrated circuit (IC) structure comprising:
a first IC layer formed above a substrate;
wherein the first IC layer comprises a network of interconnect structures comprising conductive material;
wherein the network of conductive material is configured to communicatively couple electronic devices of the IC; and
a second IC layer formed above the first IC layer;
wherein the second IC layer comprises a dielectric material that includes a top region, a bottom region, and a central region positioned between the top region and the bottom region;
wherein the top region comprises a top region backbone network strength;
wherein the bottom region comprises a bottom region backbone network strength;
wherein the central region comprises a central region backbone network strength; and
wherein the bottom region backbone network strength is higher than the than the central region backbone network strength.

18. The structure of claim 17, wherein the top region backbone network strength is less than the central region backbone network strength.

19. The structure of claim 17, wherein:
the bottom region further comprises a bottom region porosity level;
the central region further comprises a central region porosity level; and
the bottom region porosity level is less than the top region porosity level.

20. The structure of claim 19, wherein the top region porosity level is higher than the central region porosity level.
